(19) United States
(12) Patent Application Publication
(10) Pub. No.: US 2005/0032356 A1
(43) Pub. Date: Feb. 10, 2005

(54) Semiconductor device and method of manufacturing the same

(75) Inventor: Hiroshi Ishitani, Fukuoka-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/859,188

(22) Filed: Jun. 3, 2004

(30) Foreign Application Priority Data
Jun. 4, 2003 (JP) P2003-159575

(51) Int. Cl. H01L 21/4763

(52) U.S. Cl. 438/637

(57) ABSTRACT

The first metal layer 13 is formed on semiconductor substrate 11, interlayer insulation film 14 is formed to cover first metal layer 13, and the second metal layer 18 is formed on interlayer insulation film 14. Via-holes 15 are made in interlayer insulation film with via-hole isolation column 16 left. Via-hole isolation column 16 is lower in height than via-holes 15. Wolfram layers are deposited in via-holes 15 and on via-hole isolation column 16 to form wolfram plugs 17. With the structure, contact resistance between wolfram plugs and the second metal layer 18 significantly reduces.

### FIELD OF THE INVENTION

This invention generally relates to a semiconductor device with a multi-level interconnection structure and a method of manufacturing the same and, more particularly, to a semiconductor device with a multi-level interconnection structure of wolfram plugs implanted in via-holes and a method of manufacturing the same.

This application is based upon and claims the benefit of priority from the prior Japanese Patent Application No. 2003-159575, filed on Jun. 4, 2003, the entire contents of which is incorporated in this application by reference.

### BACKGROUND OF THE INVENTION

A semiconductor device is recently inclined to increase in ratio of interconnections as its requirements become higher in integration and performance. Thus, multi-level interconnections are essential to reduce the increase in area of a semiconductor device. A semiconductor device is provided with via-holes (contact holes) in which metal layer materials are filled for multi-level interconnections. Interconnection design rules become smaller in size with higher integrated-density of semiconductor devices. A groove is provided for the via-hole which is defined in isolation layers in the semiconductor device to connect an upper metal layer to a lower one. An aspect ratio of a width of the groove to a depth of the groove becomes larger as the interconnection design rules are set to be smaller in size. It is quite difficult to fill sufficient conductive materials in small radius holes.

Implanted plugs, however, are often used as a technique to fill electrically conductive materials into via-holes. A blanket wolfram chemical vapor deposition (CVD) method is carried out to form such implanted plugs. With this method, a barrier layer of TiN (titanium nitride), etc. and a blanket wolfram (W) layer are deposited in via-holes. Etching-back is then performed for a flattening process to leave the blanket wolfram layer in the via-holes to form implanted plugs. Wolfram is a highly reliable conductive material having: high heat resistance, CVD applicability, implanting suitableness, good self-generated evenness, and lower electric resistance than other high temperature melting metal and silicide.

FIGS. 5A and 5B are plan and cross-sectional views of a multi-level interconnection structure of a conventional semiconductor device, respectively. Forming first metal layer 31 made from an aluminum silicide (Al—Si) alloy, for instance, on a semiconductor substrate (not shown), a plasma CVD is applied to deposit interlayer insulation film 32. Next, insulation film 32 is etched back by etching gases for a flattening treatment of insulation film 32 while a photoresist is used as a mask. After another plasma CVD, for instance, is then applied again to deposit an different interlayer insulation film, via-holes 33 are bored through interlayer insulation film. Via-holes 33 are formed by an anisotropic etching process, such as a reactive ion etching (RIE). A CVD is then applied to deposit wolfram to fill and cover via-holes 33. Subsequently, such deposited wolfram is entirely etched back to make wolfram plugs 34 (as disclosed in Japanese Unexamined Publication 2000-232161). Finally, second metal layer 35 made from an Al—Si alloy, for instance, is formed on interlayer insulation film 32 and wolfram plugs 34.

Recently, a double-diffused metal oxide silicon (MOS) semiconductor device, for instance, requires the reduction of operative electric resistance, such as multi-level interconnection resistance and via-resistance, to highly increase output power.

In the conventional semiconductor device described above, wolfram plugs are used for the reduction of via-resistance but the sectional area of the via-hole is necessarily less than 1.0 μm□ to prevent the wolfram plug in the via-hole from pealing off. If it is less than 1.0 μm□, contact resistance between the wolfram plug and the second metal layer rises to increase operative resistance.

### SUMMARY OF THE INVENTION

Accordingly, the present invention provides a semiconductor device with a multi-level interconnection structure capable of reducing contact resistance between the wolfram plugs and metal layers and a method of manufacturing the same.

The first aspect of the present invention is directed to a semiconductor device provided with a substrate, a first metal layer formed on the substrate, a second metal layer, an interlayer isolation film formed between the first metal layer and the second metal layer, via-holes made in the interlayer film, an isolation column provided between the via-holes to isolate the via-holes which is lower in height than the interlayer isolation film, and a wolfram layer filled in the via-holes and also deposited on the isolation column to connect the first metal layer to the second metal layer.

With the structure set forth above, contact areas between the wolfram surface and the second metal layer increase so significantly that contact resistance between them can be remarkably reduced.

The second aspect of the present invention is directed to a method of manufacturing a semiconductor device consisting essentially of forming a first metal layer on a substrate, forming an interlayer isolation film on the first metal, forming a second metal layer on the interlayer isolation film, making via-holes in the interlayer isolation film, forming an isolation column in the via-holes which is lower in height than the via-holes, and depositing a wolfram layer in the via-holes and on the isolation column to contact the wolfram layer to the second metal. Thus, the method manufactures the semiconductor device in which contact areas between the wolfram surface and the second metal layer increase with the reduction of via-hole resistance.

### BRIEF DESCRIPTION OF THE DRAWINGS

A more complete appreciation of the present invention and many of its attendant advantages will be readily obtained as the same becomes better understood by reference to the following detailed descriptions when considered in connection with the accompanying drawings, wherein:

FIGS. 1A through 1C are cross-sectional views of a method of manufacturing a semiconductor device of the first embodiment of the present invention,

FIGS. 2A and 2B are cross-sectional views of a method of manufacturing a semiconductor device of the first embodiment of the present invention, respectively,

FIGS. 3A and 3B are plan and cross-sectional views of a semiconductor device of the first embodiment of the present invention, respectively,

FIG. 4 is a plan view of a semiconductor device of the second embodiment of the present invention, and

FIGS. 5A and 5B are plan and cross-sectional views of a prior art semiconductor device, respectively.

### DESCRIPTION OF THE EMBODIMENTS

Embodiments of the present invention will be explained below with reference to the attached drawings. It should be noted that the present invention is not limited to the embodiments but covers their equivalents. Throughout the attached drawings, similar or same reference numerals show similar, equivalent or same components.

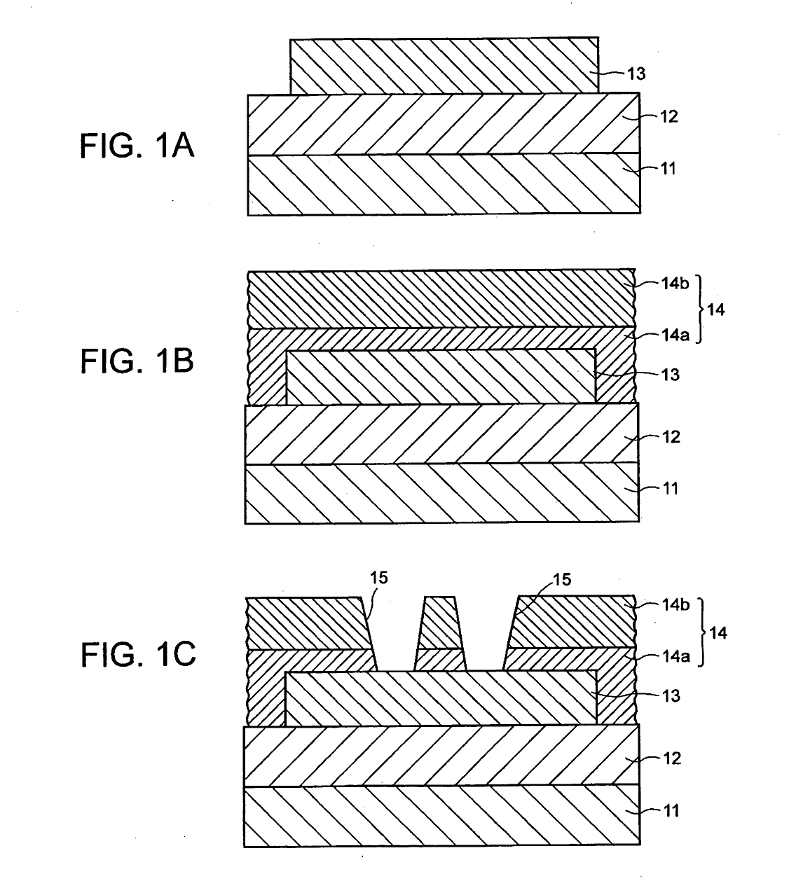

FIGS. 1A through 3B are plan and cross-sectional views to show a method of manufacturing a semiconductor device of the first embodiment of the present invention.

As shown in FIG. 1A, field insulation film 12 is formed on semiconductor substrate 11 such as a silicon substrate. A CVD or thermal oxidation method is applied to deposit 600 nm thick oxide silicon to form field insulation film 12. A magnetron suputtering method is then applied to form the first metal layer 13 made of an Al alloy on field insulation film 12. Materials of the first metal layer 13 are not shown but consist of a titanium (Ti) thin film (50 nm thick), a titanium nitride (TiN) thin film (100 nm thick), an aluminum silicide alloy (1% Al—Si-0.5% Cu) film (500 nm thick), a titanium (Ti) thin film (30 nm) and a titanium nitride (TiN) thin film (20 nm thick) formed in this order.

The above described Ti and TiN thin films are used for barrier metals to prevent Al and Si from reacting to each other. The Ti and TiN thin films (particularly, the TiN thin film) function as anti-reflection films to prevent light from reflecting from the Al alloy film in a photolithography process so that reflecting light, if any, can not affect a photoresist film. An ordinary photolithography technique including coating a photoresist film and exposure and dry etching technique (e.g., an RIE method) are carried out for patterning predetermined configurations of the barrier metal, the Al alloy film and an anti-reflection film. In this way, the first metal layer 13 is formed.

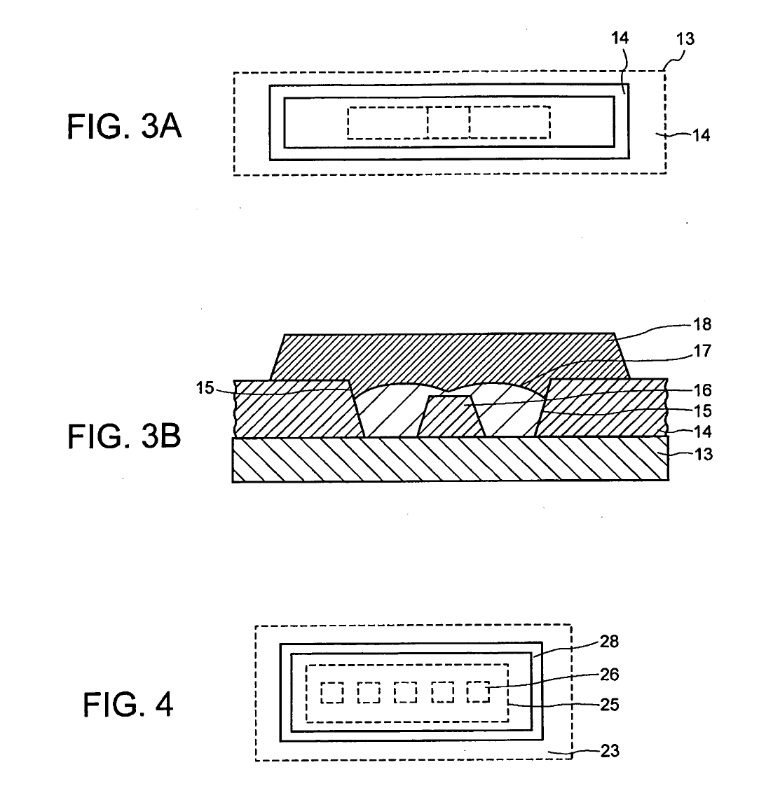

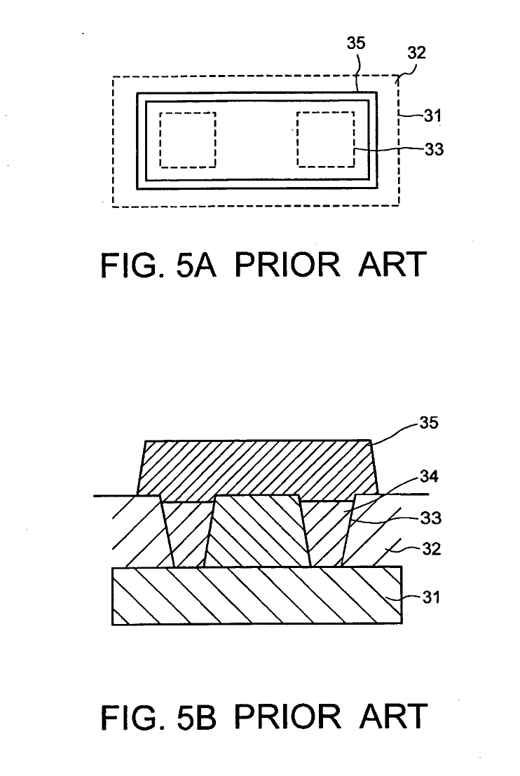

Next, as shown in FIG. 1B, the first interlayer insulation film 14a is formed on the first metal layer 13 by applying a plasma CVD method. The first interlayer insulation film 14a reduces a difference in level of the first metal layer 13. In the plasma CVD method, an oxidation film of a tetraethoxysilane film is used to form the first interlayer insulation film 14a with a thickness of 1,500 nm by plasma discharge and resolution processes of reactive gasses under reduced pressure. The first interlayer insulation film 14a is then etched back by mixed etching gasses of CF4 and O2 through a photo-resist film used as a mask to make the first interlayer insulation film 14a flat. Subsequently, another plasma CVD method is applied to deposit the second interlayer insulation film 14b made of a 500 nm thick oxidation film of tetraethoxysilane film on the first interlayer insulation film 14a. The second interlayer insulation film 14b is provided to insure appropriate pressure resistance between the first metal layer 13 and the second metal layer 18 (to be described with reference to FIG. 3B below). In this way, interlayer insulation film 14 is formed.

Next, as shown in FIG. 1C, via-holes 15 are formed in prescribed positions to connect the first metal layer 13 to the second metal layer 18. To that end, an ordinary photolithography technique including coating a photo-resist film and exposure and dry etching technique (e.g., an RIE method) are carried out for making via-holes 15 in interlayer insulation film 14 to reach the first metal layer 13. In concrete terms, after the forming of a photo-resist pattern with windows corresponding to the first metal layer 13 on inter-layer insulation film 14, an anisotropic etching method such as an RIE method, which is greater in anisotropic effect than a plasma etching method, is carried out. Such an etching RIE method, however, leaves the anti-reflection film on the first metal layer 13. To satisfy that requirement, the suitable etching conditions are, for instance, pressure of 0.8 Torr, electric power of 700 W, and etching gasses of CF₄/CHF₃/Ar/He:40/20/800/20 sccm.

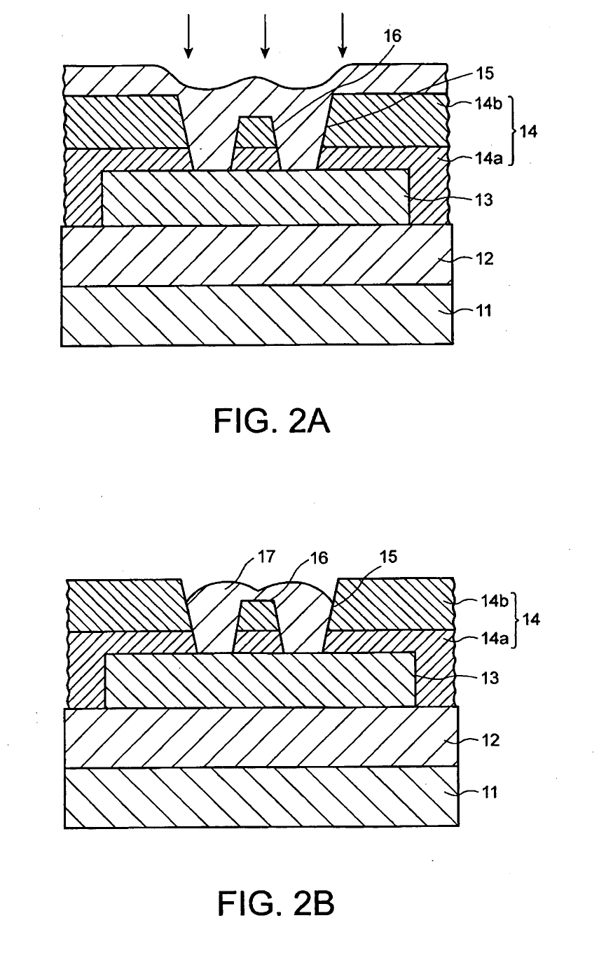

Next, the processes are carried out to form a structure shown in FIG. 2A. By using a photoresist as a mask and mixed gasses of CF4 and O2, an etching-back is performed to remove only via-hole isolation column 16 defined in via-holes 15 by a thickness of 300 nm.

Next, a sputter-etching method with inactive gasses such as Ar to clean the surfaces of via-holes 15 and a CVD method are performed to deposit 800 nm thick wolfram on interlayer insulation film 14 to form a structure shown in FIG. 2B. The CVD conditions are, for instance, pressure of 90 Torr, a temperature of 450° C. and using gasses of WF₆/H₂/Ar: 75/500/2,800 sccm. Temperatures are adjustable in the range from 425° C. to 475° C. and gas flow rates (H₂/WF₆) are also adjustable in the range from 5 to 70.

Further, an etching-back process of SF6 gas, for instance, is entirely applied to form wolfram plug 17 in via-holes 15 as shown in FIG. 2B.

Next, a process shown in FIG. 3A performs a sputter-etching method of inactive gasses such as Ar to remove oxide film, etc. from wolfram plug 17. Subsequently, a magnetron sputtering is applied to form the second metal layer 18 on wolfram plug 17. The second metal layer 18 is made of an Al alloy film (Al—Si(1%)-Cu (0.5%): 500 nm thick), a Ti film (30 nm thick) and a TiN film (50 nm thickness), which are stacked in sequence. An ordinary photolithography technique, such as photoresist coating and exposure processes, and a dry etching technique (an RIE method, etc.) are then performed for patterning prescribed configurations of the Al alloy, Ti and TiN films to form the second metal layer 18.

Multi-level interconnections formed in this way are provided with wolfram plug 17 and the second metal layer 18 connected to commonly use via-holes 15. Since via-hole isolation column 16 is created by etching back and neighboring via-holes 15 are isolated from each other and wolfram plug 17 is provided with wolfram layers implanted in via-holes 15 and a bridging wolfram layer, a contact area between the surface of wolfram plug 17 and the second metal layer 18 increases by 1.8 times in comparison with a conventional semiconductor device. Thus, contact resistance between wolfram plug 17 and the second metal layer 18 reduces significantly.

FIGS. 3A and 3B show plan and cross-sectional views of such a semiconductor device.

The semiconductor device of the first embodiment of the present invention includes wolfram plug 17 provided with wolfram layers implanted in via-holes 15 and a bridging wolfram layer so that a contact area between the surface of wolfram plug 17 and the second metal layer 18 can increase remarkably in comparison with a conventional semiconductor device and contact resistance between wolfram plug 17 and the second metal layer 18 can reduce substantially.

### THE SECOND EMBODIMENT

The second embodiment of the present invention will be described with reference to FIG. 4. As shown in FIG. 4, approximately rectangular via-hole 25 is made in an inter-layer film formed on the first metal layer 23 and a plurality of via-hole isolation columns 26 made of the interlayer film are formed in via-hole 25. A wolfram layer is filled in via-hole 25 and covers via-hole isolation columns 26. The second metal layer 28 covers the inter-layer film and the wolfram layer. Thus, with the structure, even though the maximum distance of via-hole 25 is 1.0 μm or so, a contact area between the surface of a wolfram layer implanted in via-hole 25 and the second metal layer 18 can increase remarkably.

The present invention is not limited to the embodiments described above. Although the invention has been described in its preferred form with a certain degree of particularity, it is understood that the present disclosure of the preferred form has been changed in the details of construction and the combination and arrangement of components may be resorted to without departing from the spirit and the scope of the invention as hereinafter claimed. Some components of the embodiments may be eliminated or various components from different embodiments may also be combined.

As described above, a semiconductor device of the present invention is provided with an isolation column, which is formed by etching back and neighboring via-holes are isolated from each other, electrically conductive wolfram plugs implanted in via-holes and connected each other over the isolation column, a metal layer to cover the interlayer film and the wolfram plugs so that a contact area between the surface of the wolfram plugs and the metal layer can increase remarkably in comparison with a conventional semiconductor device and contact resistance between wolfram plugs and the metal layer can reduce substantially.

1. A semiconductor device, comprising:
a substrate;
a first metal layer formed on said substrate;
a second metal layer;
an interlayer isolation film formed between said first metal layer and said second metal layer;
via-holes made in said interlayer film;
an isolation column provided between said via-holes to isolate said via-holes, said isolation column being lower in height than said interlayer isolation film; and
a wolfram layer filled in said via-holes and also deposited on said isolation column to connect said first metal layer to said second metal layer.

2. A semiconductor device according to claim 1, wherein said via-holes are less than 1.0 μm□ in horizontal, cross-sectional size.

3. A a semiconductor device, comprising:
a substrate;
a first metal layer formed on said substrate;
a second metal layer electrically connected to the first metal layer;
an isolation film formed between said first and said second metal layers;
a plurality of via-holes formed in said isolation film, said via-holes having a first upper surface which is located between adjacent ones of said via-holes and a second upper surface which is not located between the adjacent ones of said via-holes, the first upper surface being lower in height than the second upper surface;
a wolfram layer filled in said via-holes and deposited over the first upper surface to contact said first metal layer to said second metal layer.

4. A method of manufacturing a semiconductor device, comprising:
forming a first metal layer on a substrate;
forming an interlayer isolation film on said first metal layer;
forming a second metal layer on said interlayer isolation film;
making via-holes in said interlayer isolation film;
forming an isolation column in said via-holes which is lower in height than said via-holes; and
depositing a wolfram layer in said via-holes and on said isolation column to contact said wolfram layer to said second metal layer.
